(19) United States
(12) Patent Application Publication
(10) Pub. No.: US 2018/0258551 A1
(43) Pub. Date: Sep. 13, 2018

(54) (Sc,Y):AIN SINGLE CRYSTALS FOR LATTICE-MATCHED AIGaN SYSTEMS

(71) Applicant: FORSCHUNGSVERBUND BERLIN E.V., Berlin (DE)

(72) Inventors: Andrea Dittmar, Berlin (DE); Carsten Hartmann, Berlin (DE); Jürgen Wollweber, Berlin (DE); Matthias Bickermann, Berlin (DE)

(21) Appl. No.: 15/761,197

(22) PCT Filed: Aug. 31, 2016
(86) PCT No.: PCT/EP2016/070539

§ 371 Date: Mar. 19, 2018

(30) Foreign Application Priority Data
Sep. 23, 2015 (DE) 10 2015 116 068.4

(51) Int. Cl. C30B 29/40; C30B 23/06; H01L 21/02; H01L 29/20; H01L 29/205; H01L 33/32; H01L 33/00; H01L 33/06; H01L 29/15

(52) U.S. Cl. CPC C30B 29/403; C30B 23/066; H01L 21/02389; H01L 21/0254; H01L 29/2003; H01S 5/0206; H01L 33/32; H01L 33/0075; H01L 33/0025; H01L 33/06; H01L 29/155; H01L 29/205

(57) ABSTRACT

The invention concerns a method for the production of single crystal aluminium nitride doped with scandium and/or yttrium, with scandium and/or yttrium contents in the range 0.01 atom % to 50 atom % with respect to 100 atom % of the total quantity of the doped aluminium nitride, characterized in that in a crucible, in the presence of a gas selected from nitrogen or a noble gas, or a mixture of nitrogen and a noble gas:
a doping material selected from scandium, yttrium, scandium nitride or yttrium nitride or a mixture thereof
   and
a source material formed from aluminium nitride
   are sublimated and recondensed onto a seed material which is selected from aluminium nitride or aluminium nitride doped with scandium and/or yttrium.

The invention also concerns a corresponding device as well as the corresponding single crystal products and their use, whereupon the basis for novel components based on layers or stacks of layers of aluminium gallium nitride, indium aluminium nitride or indium aluminium gallium nitride is generated.

### INTRODUCTION

UV light is used for sterilization, purifying water and air, for medical applications in the case of skin diseases, to promote plant growth, for the physico-chemical investigation of solid surfaces and many more besides. UV emitters (UV light emitting diodes (LED) and UV laser diodes (LD)), sensors and related electronic components based on layers of semiconductors with large bandgaps [aluminium gallium nitride (AlGaN), indium aluminium nitride (InAlN), indium aluminium gallium nitride (InAlGaN)] can be efficient components for the UV-B and UV-C wavelength region. In this respect it is important for the number of structural and point defects in the layers to be as low as possible (dislocation density DD<10⁶ cm⁻²).

Currently, the best technology for producing layers with a small number of structural and point defects in the prior art is based on the epitaxial growth of pseudomorphically strained AlGaN layers which can only be grown on aluminium nitride (AlN) substrates with aluminium (Al) contents of more than 65%. Lattice-matched substrates are required in order to prevent the relaxation of the layers with lower Al contents in addition.

### PRIOR ART

LEDs in the near UV and visible region exhibit excellent external quantum efficiencies (EQE). In contrast, those of AlGaN-based UV LEDs with wavelengths of less than 365 nm, which are known as deep UV LEDs (DUV), are an order of magnitude lower⁽ⁱ⁾. In order to produce the components, AlGaN layers are initially deposited onto sapphire and onto single crystal AlN by means of physical vapour transport (PVT) and hydride vapour phase epitaxy (HYPE).

AlGaN/Al₂O₃ or AlN-On-Sapphire Templates

The production of AlGaN layers is currently primarily carried out on sapphire substrates and AlN-on-sapphire templates derived from them, which results in a very high defect density (>10⁸ dislocations per cm²) and is therefore highly disadvantageous as regards the properties of the component (service life, power density, efficiency etc). Because of the high defect density, such layers are practically always relaxed, i.e. no longer lattice-matched. Methods for reducing the dislocation density are known. This can, for example, be carried out by means of intermediate layers with a variable composition which alleviate the strain conditions causing the defects, or by depositing superlattices (series of thin periodic layers with a variable composition). In this regard, Khan et al developed a method for depositing AlN layers with a low defect density and improved surface morphology onto sapphire by means of MEMOCVD (migration-enhanced metal organic chemical vapour deposition^{(i,ii,iii,iv)}. They were the first to use this method to produce superlattices on c-plane sapphire DUV-LEDs by growing layers of AlN and AlN/AlGaN. By using an ammonia pulse flow method and multilayer deposition (ML), Hirayama et al succeeded in obtaining AlN buffer layers with a low defect density on sapphire^{(v)}. Sensor Electronic Technology (SET) developed commercially available UV LEDs with wavelengths of between 240 and 360 nm with a maximum EQE of 11% for the 278 nm LED and a TDD (threading dislocation density) in the range of the MQW of <10⁸ cm^{-2 (vi,vii)}, UV Craftory report a DUV-LED with a high EQE of 14.3%^{(viii)} and Hamamatsu Photonics report the shortest wavelength MQW UV-LD with a wavelength of 336 nm^{(ix)}. Epitaxial lateral overgrowth (ELO) constitutes another principal method for defect reduction, in which the layer growth is initially locally suppressed. Subsequent coalescence of the growing layer then brings about local defect-reduced regions^{(x)}. In the case of the intermediate layers, the target for a dislocation density DD of <10⁶ cm⁻² is not reached. For ELO, the size and number of the processable components is restricted to the size and number of the coalescing regions.

Free-standing AlGaN crystal wafers with a suitable Al content would be an ideal substrate for the production of pseudomorphically strained AlGaN layers. Some groups have produced thick free-standing AlGaN layers (Kyma, Richter/FBH). In this regard, a sapphire seed or an AlN-on-sapphire template is grown with the AlGaN layer and then separated from the seed. Because it is grown on a foreign substrate and because of technological challenges, however, seed wafers produced in that manner have until now in general had an insufficient structural quality (high dislocation density, macroscopic structural defects, cracks), and so no high quality AlGaN layers have been able to be deposited on such thick layers.

AlGaN on AlN-On-Si Templates, Si and AlN—SiC Templates

AlGaN on AlN-based templates grown on silicon (Si)^{(xi,xiii)} and silicon carbide (SiC)^{(xiii,xiv)} have also been reported. However, such templates have a high defect density of 10⁸ to 10¹⁰ cm⁻², high surface roughness and require expensive growth technology in order to compensate for the various thermal expansion coefficients and the lattice mismatch between the template and the foreign substrate. SiC substrates in fact have only a low lattice mismatch of 1% with AlN, but are only transparent to visible light, which makes their use in the UV LED range problematic.

AlGaN/AlN

The advantageous production of pseudomorphically strained AlGaN layers and component structures has until now been carried out on single crystal AlN substrates which had been produced by means of subilmation/recondensation on AlN or on thick single crystal AlN layers which had been produced by HVPE on PVT-AlN)^{(xv,xvi)}. The structural quality and thus the suitability for component technology is highest for single crystal AlN substrates which have been produced on crystalline AlN wafers^{(xviii)}. The AlGaN layers in the layer thickness of a few 100 nm required for component engineering, however, only remain pseudomorphically strained and low in defects if their Al content remains above 50%-65%^{(xviii,xix)}.

Globally, a number of research groups are concerned with the production of AlN bulk crystals and substrates. Recently, a number of spin-off groups have been formed. The largest (with an estimated 25-40 employees) are Crystal-IS (www.crystal-is.com), which has recently been taken over by the Japanese firm Asahi Kasei, as well as the firm HEXATECH (www.hexatechinc.com). Both firms have started to develop component production for UV-C light emitting diodes. Other smaller spin-offs such as, for example, the German firm CrystAl-N GmbH (www.crystal-n.com) as well as the firms Nitride Crystals (www.nitride-crystals.com) and Nitride Solutions (www.nitridesolutions.com) are concerned with the sale of epitaxy-ready substrates.

Until now, AlN substrates have only been commercially available in very small quantities and with erratic quality (as one-offs). In the context of publicly promoted projects, first UV light emitting diodes, UV laser diodes^{(xx)}, HEMTs^{(xxi)}, SAWs (SAW on AlN) and Schottky diodes (Xie et al, 2011,^{(xxii)} on AlN substrates have been introduced by the firms Crystal IS and HEXATECH. The above studies should generally be understood to be in the context of a “proof of concept” as neither material, epitaxy nor components have been optimized as yet.

AlGaN/GaN

The production of pseudomorphically strained AlGaN layers on gallium nitride (GaN) templates (GaN layers on AlN-on-sapphire, SiC or GaN single crystals) is only possible up to a maximum Al content of 25%-30%. Therefore, the internal quantum efficiency of light emitting diodes in the wavelength range 260-320 nm, in which AlGaN layers with a high structural quality with an Al content of 30%-65% are required, is substantially lower than for shorter or longer wavelengths⁽ⁱ⁾.

AlGaN layers on GaN-on-sapphire deposited by means of metal organic chemical vapour phase epitaxy (MOVPE) contain in the range 2.4 to 5.3×10⁸ cm⁻² or from 2.7 to 5.7×10⁹ cm⁻² threading or step dislocations. The increasing defect density (DD) is caused by an increase in the Al content in the AlGaN layer from 15% to 50%^{(xxii)}. AlGaN with low Al contents on GaN-on-sapphire can be deposited completely strained and free from cracks. With increasing Al content, the increasing relaxation of the AlGaN—GaN epilayer results in crack formation. Furthermore, the tensile stress and roughness increase with increasing Al content.

Components on ELO templates and on sapphire were compared by Song et al^{(xxiv)} AlGaN layers on GaN substrates from bulk crystals are suitable for the production of high power LEDs and LDs which operate in the visible and UV regions^{(xxv,xxvi)}. It has been able to be shown that the DD in nitride heterostructures on bulk-GaN substrates does not exceed 10⁴ cm^{-2 (xxvii)}. Compared with AlGaN structures on AlN, however, these have a lower transparency for light emission and are under tensile strain, which leads to faster crack formation^{(xxviii)}. Because of the poor availability and the high price of GaN bulk crystals, quasi-GaN bulk material with a low defect density of approximately 10⁴ cm⁻² has been produced using HVPE^{xxix}.

Although large SiC and GaN substrates are available, because of the misfit with the foreign substrate or the consequent high dislocation density already in the template, no good components have been able to be produced using this strategy (DD˜10⁸ cm⁻²).

Scandium Aluminium Nitride (ScAlN)

Layers and nanostructures formed from the material scandium aluminium nitride (Sc:AlN) are known: Bohnen et al (xxx,xxxi) have grown ScAlN nanocrystals with 5 atom % Sc on scandium nitride (ScN) film by means of HVPE; Lei et al^{(xxxii,xxxiii)} produced Sc:AlN nanostructures (with approximately 1.4 atom % Sc) by DC plasma discharge; AlN with 2.1% Sc (Sc_{0.021}Al_{0.979}N) are known as diluted magnetic semiconductors (DMS). They are ferromagnetic at room temperature, brought about by Al vacancies. Sc doping leads to a reduction in the formation energy for Al vacancies. Moram's group^{(xxxiv)} at Cambridge University have been investigating the properties and production of thin ScAlN films since 2006:
a) ScAlN with the highest possible Sc content (up to 43%) for piezoelectric applications:
   High piezoelectric coefficient predicted and measured
   Method: sputtering
b) ScAlN with “medium” Sc content for:
   epitaxiaily strained or lattice-matched ScAlN/GaN heterostructures for high electron gas concentrations in HEMTs, as a result of the high piezoelectric coefficients,
   critical layer thickness is about 2 nm for the lattice strained Sc_{0.375}Al_{0.625}N/AlN-series of layers
   Sc_{0.18}Al_{0.28}N is lattice-matched to GaN^{(xxxv,xxxci)}
   Zang^{(xxxvi)} and Moram^{(xxxv)} et al indicate the possibility of using Sc:AlN for components based on AlGaN (UV-LEDs, HEMTs). The use of Sc:AlN with a low Sc content as a substrate for AlGaN layers was not mentioned, however^{(xxxvii,xxxviii)}.
c) Sc:AlN with a “low” Sc content (approximately 2 atom % Sc, i.e. Sc_{0.02}Al_{0.90}N) is assumed to be lattice-matched by strain when deposited on an AlN substrate, i.e. the critical layer thickness for Sc_{0.02}Al_{0.98}N/AlN, for example, should be infinite^{(vii,ix)}.

Only one mention was found in the literature for (Sc,Y):AlN, namely for the growth of nanoprisms^{(xxxix)}.

The PVT process was used by Gu et al to produce ScN crystallites^{(xi)}.

A method for the production of an AlN crystal by a sublimation method is already known, in which a nitrogen atom is substituted for an oxygen atom. That method is used to produce a semiconductor crystal with a low resistance (JP 2007 26188 3 A).

A method for the production of an AlN single crystal by sublimation in which the source material can be doped is also known (US 2015/0218728 A1).

Furthermore, sublimation assemblies which are suitable, inter alia, for the growth of doped SiC single crystals are also known. In this regard, the separated storage and heating of doping and source material in the sublimation growth chamber is described. As a rule, the doping element is guided to the seed over a long path via the gas phase (DE 10 2005 049 932 A1 and DE 10 2008 063 129 A1).

A method for the production of long SiC or AlN bulk crystals is also known. A bulky intermediate block is placed between the seed and the source material. However, this does not function as a diaphragm. The source material is initially deposited on the underside of the block and then sublimated again on the side facing the seed. Very long bulk crystals can be produced in this manner (DE 10 2009 016 132 A1).

### The Present Invention

The objective of the present invention is to provide substrates which can be used to produce low defect, pseudomorphically compressively strained aluminium gallium nitride (AlGaN) layers even at low aluminium contents, preferably <65 atom % Al. Aluminium contents in the range 0.001 atom % to 60 atom % Al, most preferably in the range 0.01 atom % to 50 atom % A1 are more preferred.

This objective is achieved by means of the method according to claim 1 and by means of a device according to claim 20, as well as with the corresponding single crystal products according to claim 10, 11, 12, 13 or 14 and their use according to claims 15 to 17. The objective is also achieved by means of the components according to claim 18. Further preferred embodiments are defined in the dependent claims.

In other words, the objective is achieved by means of a method for the production of single crystal aluminium nitride doped with scandium and/or yttrium, with scandium and/or yttrium contents in the range 0.01 atom % to 50 atom % with respect to 100 atom % of the total quantity of the doped aluminium nitride, wherein the method is characterized in that in a crucible, in the presence of a gas:
a doping material selected from scandium, yttrium, scandium nitride or yttrium nitride or a mixture thereof

and
a source material formed from aluminium nitride
   are sublimated and recondensed onto a seed material which is selected from aluminium nitride or aluminium nitride doped with scandium and/or yttrium.

Products in Accordance with the Invention

By using the method in accordance with the invention, both single crystal aluminium nitride doped with yttrium and single crystal aluminium nitride doped with scandium and yttrium, as well as single crystal aluminium nitride doped with scandium can be produced.

Single crystal aluminium nitride doped with scandium which is produced in accordance with the method of the invention preferably has geometric dimensions of at least 3 mm×3 mm×100 μm. Similarly, single crystal aluminium nitride doped with yttrium which is produced in accordance with the method of the invention preferably has geometric dimensions of at least 3 mm×3 mm×100 μm. Similarly, single crystal aluminium nitride doped with scandium and yttrium which is produced in accordance with the method of the invention preferably has geometric dimensions of at least 3 mm×3 mm×100 μm.

As mentioned above, the aluminium nitride doped with scandium and/or yttrium has scandium and/or yttrium contents in the range 0.01 atom % to 50 atom %, with respect to 100 atom % of the total quantity of the doped aluminium nitride. Preferably, scandium and/or yttrium contents in the range 0.1 atom % to 25 atom %, more preferably in the range 0.5 atom % to 10 atom %, respectively with respect to 100 atom % of the total quantity of the doped aluminium nitride, is obtained.

When both scandium and yttrium are present, the scandium content may be in the range 0.1% to 99.9% with respect to the total quantity of scandium and yttrium. This is also the case for the yttrium content, i.e. it may be in the range 99.9% to 0.1% with respect to the total quantity of scandium and yttrium.

### Growth of (Sc,Y):AlN Bulk Crystals in Detail

The principal system and process control engineering corresponds to that for the production of AlN single crystals as described, for example, by T. Paskova and M. Bickermann in the article “Vapor Transport Growth of Wide Bandgap Materials”, in: The Handbook of Crystal Growth, Second Edition, Vol 2A: Bulk Crystal Growth—Basic Technologies, P. Rudolph (ed.), Elsevier Science Ltd. 2015, ISBN: 978-0-44463-303-3, Chapter 16, as well as by C. Hartmann, A. Dittmar, J. Wollweber, M. Bickermann in the article “Bulk AlN Growth by Physical Vapor Transport”, Semicond. Sci. Technol. 29 (2014) 084002.

However, for the production of (Sc,Y):AlN, the modifications in accordance with the invention as described below are necessary.

Details of the Method in Accordance with the Invention

The production of (Sc,Y):AlN is carried out by means of a sublimation/recondensation process in a crucible starting from scandium (Sc), scandium nitride (ScN), yttrium (Y) or yttrium nitride (YN) or a mixture of these substances as the doping material, and aluminium nitride (AlN) as the source material, as well as AlN or (Sc,Y):AlN itself as the seed material.

The gas used (synonym: process gas) is nitrogen or a noble gas, preferably argon, or a mixture of nitrogen and noble gas, preferably argon. Thus, preferred gases are nitrogen (N₂), argon (Ar) or a mixture thereof (N₂+Ar). The process gas is not the only gaseous component which is present inside the device in accordance with the invention which will be described in more detail later on as the method is carried out. Rather, in addition to the process gas, other gaseous moieties which originate from the sublimation of the source material and the doping material are present. The total pressure during the method is correspondingly defined as the sum of all of the partial pressures, i.e. the sum of the pressure of the process gas and the partial pressure of the gaseous moieties which originate from the sublimation of the source material and the doping material.

Production is carried out at temperatures of 1500° C. to 2700° C. with the addition of or with a constant stream of N₂ or Ar or N₂+Ar, at system pressures of 10 to 1200 mbar, preferably between 200 and 1000 mbar, particularly preferably between 500 and 900 mbar. The term “system pressure” should be understood to mean the total gas pressure, i.e. the sum of the pressure of the process gas together with the partial pressures of the gaseous moieties which originate from the sublimation of the source material and the doping material.

The AlN source material is purified before being used for growth, preferably by sublimation or sintering, in particular in order to remove the oxygen and carbon impurities. For the growth, the source material is used as a powder or as polycrystalline articles.

The dopants Sc or ScN, Y or YN (the doping material) may also be used without any further purification. When using the pure metals Sc and Y, nitriding, i.e. the formation of ScN or YN in situ, is carried out as the crucible is heated up.

Various orientations of single crystal AlN substrates (wafer) or AlN wafers which have already been doped with Sc, Y or both, are used as the seed (seed material). In order to allow condensation onto the seed or the seed substrate and thus to allow crystal growth, the temperature of the source material must be higher than that of the seed or the seed substrate.

In particular, the temperature of the source material is 1K to 300K higher than the temperature of the seed material. Preferably, the temperature of the source material is 50K to 200K, more preferably 100-150K higher than the temperature of the seed material. The advantageous temperature of the AlN source material in the production of (Sc, Y):AlN is in the range 1700° C. to 2700° C. (preferably in the range 2100° C. to 2400° C.). The advantageous temperature of the doping material in the production of (Sc, Y):AlN is in the range 1900° C. to 3100° C. (preferably in the range 2100° C. to 2800° C.). The advantageous temperature of the seed is in the range 1400° C. to 2400° C. (preferably in the range 1800° C. to 2100° C.).

In a further advantageous embodiment, as an alternative to or as a supplement thereto, the temperature of the doping material is 1K to 400K higher than the temperature of the source material.

Preferably, the temperature of the doping material is 50-300K, more preferably 100-200K higher than the temperature of the source material.

Highly advantageously, then, the temperature relationship is as follows:

T(seed)<T(source material)<T(doping material)

or

T(doping material)>>T(AlN−source material)>T(seed)

This overcomes a problem which is central in (Sc,Y):AlN growth, namely that the Sc and Y partial pressure (also that of the nitrides) is lower than that of Al over AlN (FIG. 1).

In an alternative embodiment, the temperature of the doping material is the same as or lower than the temperature of the source material.

T(doping material)less than/equal to T(AlN−source material)>T(seed)

In this alternative embodiment, advantageously, a (mechanical) inhibition, i.e. an inhibiting means, is used in order to inhibit diffusion of the source material.

In a preferred embodiment, the seed material is disposed or can be disposed in the crucible separated from or separable from the source and doping material, preferably separated from or separable from or disposed or can be disposed above the source and doping material. In a particularly advantageous arrangement, the seed in the crucible is retained in a mechanical, chemical or physico-chemical manner above the source and doping material, preferably on the crucible cover, and the source as well as the doping material are located in the lower and middle region of the crucible and, for example, the source material is resting on the floor of the crucible so that it does not have to be held in a specific manner.

In an advantageous arrangement, the doping material is spaced from and, in an advantageous embodiment, is in a region of the crucible with a higher temperature or at a higher temperature than the source material. In other words, in the crucible, the source and doping materials are spatially separated or separable or spaced apart or can be spaced apart from each other. This means that the relatively rapidly cooling vapour from the doping material can reach the seed material. Usually, at least a portion of the source material lies in the lower region of the crucible and the doping material is disposed or can be disposed above it. This also encompasses arrangements in which the doping material is actually separated from but is at least partially embedded in the source material, for example in an inner crucible. In particular embodiments, at least a portion of the doping material is also present in the lower part of the crucible, wherein the spatial separation of the source and doping material is preserved. Insofar as the doping material in one region of the crucible is at the same or at a lower temperature than that of the source material, an inhibitor, preferably mechanical, is added, i.e. an inhibiting device, which prevents diffusion of the source material.

In an alternative advantageous arrangement, the doping material may also be mixed with AlN source material or sintered with the AlN source material, or be in the form of scandium and/or yttrium-doped AlN. In other words, in the crucible, the source and doping material are completely or partially mixed, sintered or already present as aluminium nitride doped with scandium and/or yttrium. In general, the doping material and source material are intimately mixed, although it is not important whether the mixing is homogeneous or inhomogeneous (for example doping material on the hot crucible floor). The temperature gradient between the source material (for example AlN) or doping material and the seed is preferably between 1 and 100 K/cm; more preferably between 2 and 30 K/cm.

In order to obtain a sufficient/different/desired Sc or Y content in the growing AlN crystal, a special experimental protocol is necessary which includes the use of an advantageous growth chamber construction. The following have a decisive influence on the result:

a) the temperature range in the crucible, in particular the temperature differences between the source material and seed, between the source material and doping material as well as the temperature gradients at the surface of the source material, at the surface of the doping material and at the surface of the seed, as well as, connected therewith,
b) the geometric position of the doping material in the crucible, in particular with respect to the temperature therein and the position relative to the source material and to the seed.

The temperature as well as the temperature range in the crucible are adjusted by the heating power, the position of the induction coil and/or the resistance heater with respect to the susceptor, the position of the crucible in the susceptor, appropriate lines for the gas streams and changes in the position, shape, geometry and choice of materials of the various parts of the growth chamber assembly (crucible including the parts and means therein, susceptor, heat insulation, pyrometer holes, etc).

Details Regarding the Crucible in Accordance with the Invention

In general, the assembly comprises a crucible the upper region of which can be closed with a cover, thermal insulation, which surrounds the floor of the crucible and at least part of the sides (lower region of the crucible) as well as a heating means, preferably an induction coil (connected to an appropriate radio frequency generator), which surrounds at least a portion of the crucible as the sides thereof.

The crucible is advantageously in a graphite assembly consisting of a felt and susceptor. An alternative advantageous assembly includes a susceptor formed from tungsten (W), tantalum carbide (TaC) or tantalum nitride (TaN) and a heat insulation formed from graphite felt, porous nitride, carbide or oxide high temperature ceramic, and/or from tungsten or tantalum heat deflectors. Heating is preferably carried out inductively by means of coils or as resistance heater. The aim is to have a growth rate in the range 1 to 800 μm/h, preferably 30 to 300 μm/h.

Preferably, the crucible material is TaC, tantalum (Ta), tungsten carbide (WC), W, TaN or a mixture thereof. A seed support may also be prepared from these materials, and may be connected to the crucible. The crucible may also act as the susceptor.

A heating means (for example an inductive coil or a resistance heater) is disposed or can be disposed outside the crucible, preferably at least in the lower region of the crucible, whereupon the temperature which is produced by the heating means, as described above, is in the range 1500° C. to 2700° C.

The device in accordance with the invention comprises, preferably consists of a crucible modified in accordance with the invention and is characterized in that in a first region which is preferably the upper region of the crucible, the crucible is provided with a first means in which a seed material can be accommodated or is accommodated or which can hold a seed material, and in a second region of the crucible, which is preferably the lower region of the crucible, at least one second means is provided in which a source and/or a doping material may be or is/are accommodated. In particular, when both a source and doping material are present as explained above, this may be at least one second means of the lower (inner) region of the crucible itself.

By spatially separating the source and doping material, the at least one second means may comprise at least two said second means, of which one is configured to accommodate the source material and the other is configured to accommodate the doping material. Preferably, the mean separation of the second means for accommodating the doping material from the first means for accommodating the seed material is less than the mean separation of the second means for accommodating the source material and the first means for accommodating the seed material. In this embodiment again, one of the two devices may be the lower region of the crucible itself, which preferably contains the source material or constitutes the second means for accommodating the source material.

Preferably, in addition to the crucible in accordance with the invention, the device in accordance with the invention also comprises a heating means (induction coil or resistance heater) which surrounds at least a portion of the outside of the crucible at the height of the second region per se.

Preferably again, the heating means is configured or configurable such that the temperature in the region of the second means for accommodating the source material is 1K to 300K higher, preferably 50K to 200K higher, more preferably 100-150K higher than the temperature in the region of the first means for accommodating the seed material.

As an alternative or in addition to installing the heating means, the temperature profile described above is obtained by the special design of the crucible itself or by the positioning of the (devices for accommodating) the seed, source and doping material.

Optionally, in particular when the source and doping material are spatially separated, electrical contacts formed from graphite, TaN. TaC or W may be provided to supplement the heating. These are preferably installed outside the crucible at the level of the doping material or at the level of the second means for accommodating the doping material.

Preferred embodiments of the crucible in accordance with the invention will now be described in detail, wherein the crucible has a cover (crucible cover) in every form:

In one embodiment in accordance with the invention as shown, by way of example, in FIG. 2.1, the seed 1 or the first means for accommodating the seed is fixed to the crucible cover 2. The lower portion of the crucible 3 forms the second means for accommodating the source and doping material (4, 5). The doping material 5 and source material 4 may be intimately mixed therein, but it is not important in this regard as to whether the mixture is homogeneous or inhomogeneous (for example doping material on the hot crucible floor). The separation between the seed and surface of the source material, i.e. between the first means for accommodating the seed and the upper boundary of the upper crucible region which forms the second means for accommodating the doping and source material, is at least 1 mm, preferably between 1 and 50 mm.

In an alternative embodiment, in which the seed 1 or the first means for accommodating the seed 1 is positioned as before on the crucible cover 2, the source material 4 and doping material 5 are separated into different zones of the crucible 3 as can be seen, for example, in FIGS. 2.2a and b. This alternative embodiment uses the lower inner region of the crucible itself as the first second means for accommodating the source material 4. Disposed in the upper region of the crucible, i.e. still below the crucible cover 2 and the body 1, is a second means for accommodating the doping material. As an example, to this end, FIG. 2.2a shows an apertured diaphragm 6 as a partial diffusion barrier and FIG. 2.2b shows a further, separate (smaller) crucible 7. This further, separate crucible 7 is preferably supplemented by an apertured diaphragm 6 which is disposed over the separate crucible but under the seed and crucible cover and which covers the source material but not the opening of the separate crucible 7. Preferably, in this embodiment, the position of the further separate crucible 7 within the source material can be freely selected. The apertured diaphragm 6 in both embodiments has the function of inhibiting the vaporization of the source material by mechanically preventing diffusion. The further, separate crucible 7 also acts, inter alia, to additionally inhibit vaporization of the source material by kinetic inhibition or mechanical inhibition of the diffusion. The respective sizes of the two crucibles can be freely selected; as an alternative/supplement, the size of the aperture in the apertured diaphragm may also be freely selected.

The material of the further, separate crucible 7 is preferably selected from TaC, Ta, WC, W, TaN or mixtures thereof.

Optionally, electrically conductive contacts 13, preferably formed from TaC, TaN, W or graphite, are present as supplemental heating, which are attached outside the crucible 3 at the level of the doping material or of the second means for accommodating the doping material (for example apertured diaphragm 6).

The separation between the seed and surface of the source material or doping material, i.e. between the first means for accommodating the seed and the upper boundary of the upper crucible region which forms the second means for accommodating the doping and source material, is at least 1 mm, preferably between 1 and 50 mm.

In an alternative embodiment in which the seed or the first means for accommodating the seed 1 is positioned as before on the crucible cover 2, the source material 4 and the doping material 5 are in a modified crucible 11, as can be seen by way of example in FIGS. 2.3a-d. This crucible 11 has a thicker wall in the lower region than in the upper region 11a, i.e. the region closer to the seed 1. The crucible wall 11b (hatched) which is thicker compared with the upper region 11a extends over 1-90%, preferably over 10-60% of the crucible height (measured from the floor to under the cover) and extends completely round it. Compared with the diameter of the crucible (the extent inside the crucible), the thicker wall 11b extends over 1-90%, preferably over 10-30% of the crucible radius. In the lower region, the thicker wall 11b acts to support setting up the variable temperature zones. Preferably, it has an upper surface 11c (upper face 11c) which is approximately horizontal, i.e. parallel to the crucible floor. The term “approximately horizontal” encompasses being parallel to the crucible floor, but also with inclinations of ±. 10%, preferably ±5%. The second means for accommodating the doping material 5 is either formed by the upper side 11c of the thicker crucible wall 11b or is an appropriate device, for example an apertured diaphragm 8, which is applied to the upper side 11c of the thicker crucible wall 11b or the heat shields 9. In preferred variations of this embodiment, in the lower region of the inside of the crucible, one or more heat shields 9 are positioned which may be in any configuration.

These preferably have a tubular shape and extend over 1-90%, preferably over 10-60% of the height of the crucible. In a particularly preferred variation, the height of the heat shields is approximately that of the thicker crucible wall 11b, i.e. there is only a 1-10% difference between the height of the thicker crucible wall and the height of the heat shield 9. Inside the thicker crucible walls and in the preferred variation with one or more heat shields 9 even within the heat shield, the second means for accommodating the source material 4 may be disposed or can be disposed. This is preferably in the form of a crucible 10 and may be described as the separate, inner crucible 10 in the lower region. It should be understood that the height of this separate crucible 10 is 1-90%, preferably 10-60% of the crucible height; preferably, the height of the separate crucible 10 is less than the height of the thicker crucible wall 11b or less than the height of the heat shield(s) 9. Similarly, it should be understood that the diameter of the crucible is selected such that the crucible 10 within the thicker crucible wall 11b of the crucible 11 and when heat shield(s) 9 is/are present may be positioned within said heat shield.

Alternatively or in addition, a further separate device, for example an apertured diaphragm 8, may be present or can be installed on the heat shield(s) on which doping material can (also) be positioned. This further separate device or component of the second means for accommodating the doping material is also present, if applicable.

Optionally, in each and any embodiment of the modified crucible 11, for additional heating of the doping material 5, graphite contacts 13 may be installed on the outside of the crucible 11. These are preferably attached or attachable outside the crucible 11 at the level of the second means for accommodating the doping material.

In a preferred alternative of the modified crucible with thicker crucible wall 11b, at least one additional crucible opening 12 is provided, preferably at the floor of the crucible. This acts to reduce vaporization of the source material (cooling).

The material of the smaller crucible 10, the second means for accommodating the doping material (for example apertured diaphragm 8) as well as the heat shield(s) 9 is selected from TaC, Ta, WC, W, TaN or mixtures thereof.

Different temperature zones in the crucible may additionally be set by specific selection of the parameters such as, for example:
variable size of the crucible opening 12,
electrical contact 13 for additional heating of the doping material.

In an alternative embodiment, in which the seed or the first means for accommodating the seed 1 is positioned as before at the crucible cover 2, the source material 4 and the doping material 5 may be in a modified crucible 16, which is described as being a “long crucible”. In this regard, the various temperature zones for the seed, doping material and source material can be adjusted better by displacing the crucible within the induction coil than in the embodiments described above. This means that the first means for accommodating the seed, the second means for accommodating the doping material and the second means for accommodating the doping material are separated from each other by so much that the crucible with the source material 4, for example, is outside below the induction coil/resistance heater (cooling of source material), the doping material is in the centre of the induction coil (hottest zone) and the seed is outside above the induction coil (coldest zone).

The second means for accommodating the doping material may be formed by any device, for example a diaphragm 14 or a step 15 which is disposed under the first means for accommodating the seed but above and spatially separated from the second means for accommodating the source material. This is shown in FIGS. 2.4a-b by way of example.

Further Use of the Products in Accordance with the Invention

The single crystalline scandium- or/and yttrium-doped AlN ((Sc,Y):AlN) produced in accordance with the invention is used as a quasi-eigen substrate for low defect pseudomorphically strained AlGaN layers. The lattice constant for the quasi-eigen substrate is prescribed by the level of the scandium or/and yttrium content in the quasi-eigen substrate. The level of the scandium or/and yttrium content can be set during the production of the quasi-eigen substrate and thus be matched to the desired lattice constant and/or strain of the AlGaN layer. The restrictions as regards layer thicknesses and Al contents which result in pseudomorphically strained AlGaN layers are lessened when the quasi-eigen substrate is used in epitaxy compared with using pure AlN substrates.

Even small (Sc, Y) contents of a few atomic percent are sufficient to obtain a quasi-eigen substrate which is lattice-matched to, for example, Al_{0.5}Ga_{0.5}N layers.

The single crystal aluminium nitride doped with scandium produced in accordance with the invention is used as a substrate (wafer) for the production of layers or stacks of layers formed from aluminium gallium nitride, indium aluminium nitride or indium aluminium gallium nitride, preferably with a layer thickness of more than 2 nm, more preferably with a layer thickness of 100 nm to 50 μm.

Similarly, the single crystal aluminium nitride doped with yttrium is used as a substrate (wafer) for the production of layers or stacks of layers formed from aluminium gallium nitride, indium aluminium nitride or indium aluminium gallium nitride, preferably with a layer thickness of more than 2 nm, more preferably with a layer thickness of 100 nm to 50 μm.

In addition, the single crystal aluminium nitride doped with scandium and yttrium is used as a substrate (wafer) for the production of layers or stacks of layers formed from aluminium gallium nitride, indium aluminium nitride or indium aluminium gallium nitride, preferably with a layer thickness of more than 2 nm, more preferably with a layer thickness of 100 nm to 50 μm.

The expression “layers or stacks of layers” respectively encompasses individual or a plurality of layers, i.e. in an extreme case just a single layer may be present. A stack of layers may respectively consist of individual or a plurality of stacked layers.

The layers or stack of layers produced from aluminium gallium nitride, indium aluminium nitride or indium aluminium gallium nitride produced thereby, produced by means of single crystal aluminium nitride substrates doped with scandium and/or yttrium, are used as components for the UV-B and UV-C wavelength regions (220-340 nm).

### Components

Semiconductor components may be produced from the aforementioned layers or stacks of layers on single crystal aluminium nitride substrates doped with scandium and/or yttrium using the known structuring and metallization processes and using a suitable stacking and bonding technique. Preferably, the layers, stack of layers or parts thereof form the electrically active regions of the component. Components in accordance with the invention thus comprise layers or a stack of layers of aluminium gallium nitride, indium aluminium nitride or indium aluminium gallium nitride, which are on single crystal aluminium nitride substrates doped with scandium and/or yttrium (the quasi-eigen substrate). These layers or a stack of layers of aluminium gallium nitride, indium aluminium nitride or indium aluminium gallium nitride are also known as the “low defect first layer” which may also be abbreviated to the “first layer”. Optionally, at least one further layer formed from crystalline aluminium nitride or a layer formed from aluminium gallium nitride which contains more aluminium (as an atomic percentage) than the “(low defect) first layer” which contains the layers or stack of layers of aluminium gallium nitride, indium aluminium nitride or indium aluminium gallium nitride, is applied to this low defect first layer. It is known that the physical (in particular electrical, optical, mechanical, thermal and acoustic) properties of the individual layers or stack of layers can be specifically adjusted by appropriate adjustment or variation of the concentration of the chemical elements constituting the layers (optionally aluminium, gallium, indium, nitrogen) as well as further chemical elements which act to adjust the properties (dopants, impurities). The invention can now be used to produce layers or stacks of layers formed from aluminium gallium nitride, indium aluminium nitride or indium aluminium gallium nitride.

Advantageous semiconductor components in accordance with this invention are components formed from the stacks of layers mentioned above, in which, in accordance with the invention, the layer lying directly above the quasi-eigen substrate or the pack of layers lying directly above the quasi-eigen substrate (“first layer”) has the desired lattice constant and/or strain due to lattice-matching to the quasi-eigen substrate in a manner such that the density of the locally extended structural defects formed by a residual lattice mismatch the extent of which in the direction of the layer surface is larger than the extent in the plane of the layer (penetration dislocations) in this “first layer” is less than 10³ cm⁻² (“low defect first layer”). It is also known that a low defect density in the first layer also leads to a lower defect density in the other layers if the process used to produce the layers is suitable. The low defect first layer forms an electronic or optical guide layer for the component produced on the quasi-eigen substrate.

In an advantageous arrangement for a semiconductor component, a “low defect first layer” consisting, as described above, of layers or stacks of layers formed from aluminium gallium nitride, indium aluminium nitride or indium aluminium gallium nitride is produced directly (i.e. without further intermediate layers) on the quasi-eigen substrate. In contrast to solutions to the problem applied up until now, this means that structuring of the substrate which is employed, often “nucleation layers” applied at low temperatures and “masking layers” or “buffer layers” used to reduce the structural defects, can be dispensed with. A very thin layer formed from crystalline aluminium nitride or a layer formed from aluminium gallium nitride which contains more aluminium (as an atomic percentage) than the “low defect first layer” is applied to the “low defect first layer” which has the desired properties. Both layers are contacted by other layers, stacks of layers and/or metallizations. It is known that such component structures can be used as HEMTs. The construction of the component is substantially simplified by using the quasi-eigen substrate and dispensing with nucleation, masking and buffer layers. Because of the resulting low density of penetration dislocations, the properties of the component are improved. The said components function well when the layers are produced on a metal-polar surface with retention of the polarity. However, it may also be advantageous for the very thin layer to consist of crystalline gallium nitride or a layer of aluminium gallium nitride or indium aluminium nitride which contains less aluminium (as an atomic percentage) than the “low defect first layer”, as in this case what is known as the two-dimensional electron gas is on the other side of the boundary (depending on the polarity of the surface) between the “low defect first layer” and the very thin layer. If necessary, what is known as a “capping layer” and/or a passivation layer has to be applied to the very thin layer, as is known in the prior art.

In a further advantageous arrangement for the semiconductor component, a plurality of alternating very thin layers are produced on the “low defect first layer” which differ in the atomic concentration of the constituent elements. It is known that such alternating series of layers can increase the electrical conductivity of the stack of layers as a superlattice structure without producing large mechanical strains or structural defects. Other alternating series of layers can be used as a Bragg mirror, for example in vertical laser components. These structures can also profit from the inventive simpler construction of the component on the quasi-eigen substrate and from the low defect density in the layers.

In a further advantageous arrangement, the composition of the “first low defect layer” is selected in a manner such that it simultaneously forms an electronic or optical guide layer (conducting layer, blocking layer or guiding layer) for the component produced on the quasi-eigen substrate, wherein the component itself acts to produce and/or detect electroluminescence or laser light in the wavelength region of 210 nm 380 nm (UV-LED, UV laser diode, UV sensor). In the current prior art, such components and thus also the electronic or optical guide layers are deposited on a nucleation, masking or buffer layer. Because of the advantageous production of the “low defect first layer” on the quasi-eigen substrate, these can be dispensed with.

The invention will now be explained in more detail with the aid of examples which are not limiting in any way.

### EXAMPLES

### Example 1—Investigation of Nitriding of Sc by TG/DTA Measurements

Sc in graphite crucible in stream of N₂ to 1640° C., rate of heating 10 K/min

Nitriding of scandium in accordance with the following reaction:

Sc+½N₂-->ScN

commences from 1000° C., with a strong exothermic peak at 1375° C.

The phase composition of the reaction product produced pure ScN.

### Example 2—PVT of Sc:AlN (Crucible Design as Shown in FIG. 2.1)

Up to 1% by weight of Sc intimately mixed into AlN source material

Tp_{y,o}=2030° C., t=15 h; growth rate 180 μm/h

AlN seed, h=5 mm; top diameter 3 mm

As a result, a hexagonally grown crystal was obtained:

Diameter 7×8 mm; h=8 mm (sample reference FZ_221, see FIG. 3)

The crystal was sawn into one a-plane wafer and four c-plane wafers. Chemo-mechanical polishing (CMP) was used to obtain uniform thin layers (both sides). Sc was found in all of the wafers (EDX, XRF), with uniform Sc distribution in c-plane wafers (EDX, XRF).

The result of the X-ray fluorescence analysis (XRF, line scan c-plane capping layer) is shown in FIG. 4. The ScN concentration was between 0.3 atom % and 0.35 atom % this corresponded to ScN in AlN or 0.65 atom % to 0.7 atom % Sc in ScAl.

This gives: Sc_{0.007}Al_{0.993}N

The variations in the Sc concentration result from the unevenness of the capping layer.

The result of the X-ray fluorescence analysis (XRF, line scan c-plane capping layer) in the vicinity of the seed is shown in FIG. 5.

The ScN concentration was between 0.3 atom % and 0.4 atom % ScN in AlN, or 0.6 atom % to 0.8 atom % Sc in ScAl. An increasing Sc concentration was observed in en-plane grown AlN. This gives as a maximum: Sc_{0.008}Al_{0.992}N

The increasing Sc concentration in the a-plane wafer (XRF) was 0.4 atom % ScN; the result of the XRF is shown in FIG. 6. The ScN concentration was between 0.3 atom % and 0.4 atom % ScN in AlN;

The rocking curve for the capping layer of sample FZ_221 (as-grown) was 33.1 arcsec and is shown in FIG. 7 (primary beam apertures 2 and 0.05 mm; open detector).

The result indicates the presence of several grains.

Determination of Lattice Parameters (XRD Etc).:

| | AlN | ScAlN | |
|---|---|---|---|
| Sample | CH879 | FZ_221 (capping layer) | |
| a | 3.1113 | 3.11287 | 0.00157 Å |
| c | 4.9812 | 4.981996 | |

For ScₓAl₁₋ₓN, using the Da according to Morarn (2014) produced:

Sc_{0.009}Al_{0.991}N—this corresponds to 0.9 atom % Sc or 0.45 atom % ScN

The result compared well with the XRF values given above.

### Example 3—PVT of Sc:AlN with Crucible Configuration as Shown in FIG. 2.2b (Sample FZ_266)

Tp_{y,o}=2030° C.; t=15 h; p=600 mbar

The aim was to obtain a very good quality hexagonal crystal:

One centre of growth (Nomarski),

Rocking curve, capping layer=21.4 arcsec (shown in FIG. 8)

### Lattice Constant (XRD):

| | AlN | ScAlN | |
|---|---|---|---|
| Sample | CH879 | FZ_266 (capping layer) | |
| a | 3.1113 | 3.1132 | 0.0019 Å |
| c | 4.9812 | 4.9822 | |

For ScₓAl₁₋ₓN, using the Da according to Moram (2014) produced:

Sc_{0.0097}Al_{0.9903}N—this corresponds to 0.97 atom % Sc or 0.48 atom % ScN

The XRD line scan on the capping layer of the sample FZ_266 produced a ScN content of approximately 0.4 atom % ScN.

Overall, the agreement with the XRD values was good.

### Example 4—Doping of AlN with Y or (Sc,Y)

Doping of AlN with yttrium or (Sc,Y) was carried out in a manner analogous to that for scandium. The success of the doping was based on the comparatively small partial pressure difference for Sc and Y (FIG. 1) in connection with similar ionic radii of 73 pm for Sc and 93 pm for Y.

### BRIEF DESCRIPTION OF THE FIGURES

FIG. 1 partial pressure of Sc, Y and Al in presence of AlN as a function of temperature at 600 mbar (FactSage);

FIG. 2.1 crucible 3 with crucible cover 2; inside is the source material 4 and the doping material 5; the seed 1 is attached to the cover 2;

FIG. 2.2 source material 4 and doping material 5 separated in different zones of the crucible

2.2a) the doping material 5 is on an apertured diaphragm 6 which functions to inhibit the vaporization of the source material kinetically;

2.2b) the doping material 5 is in a small crucible 7 below the seed 1; the design also includes an apertured diaphragm 6 on the source material 4;

FIG. 2.3 crucible 11, 11a, 11b with different wall thicknesses with separate crucible 10 in the lower region, heat shield 9 (crucible height may exceed that of heat shield), seed 1 on crucible cover 2; additional crucible opening 12 to reduce vaporization of source material (cooling)

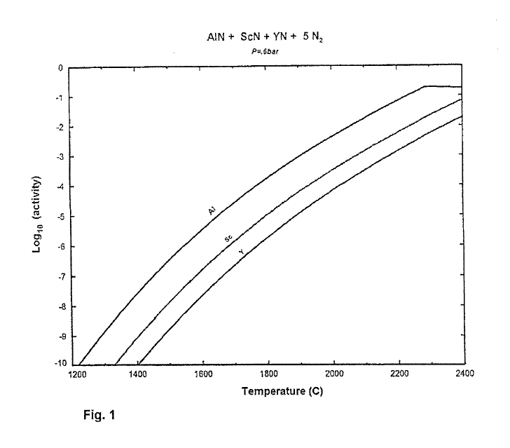

2.3 a) doping material 5 in central, hot region of crucible on a step or the like, i.e. on surface 11c;

2.3 b) doping material 5 on small apertured diaphragm 8 which is either on the inner heat shield or directly on the crucible 10, apertured diaphragm serves to accommodate the doping material and for “orientated” vaporization of source material 4 in the direction of the seed 1;

2.3 c) doping material 5 both on apertured diaphragm (small) 8 and on step in crucible 11, i.e. on surface 11c; apertured diaphragm 8 is either on inner heat shield or directly on the crucible 10;

2.3 d) doping material 5 both on apertured diaphragm (small) 8 and on step in crucible 11, i.e. on surface 11c; apertured diaphragm 8 is either on inner heat shield or directly on the crucible 10; additional heating of the doping material 5 by graphite contact 13 (formed from graphite, etc) between susceptor and crucible wall installed outside the crucible 11;

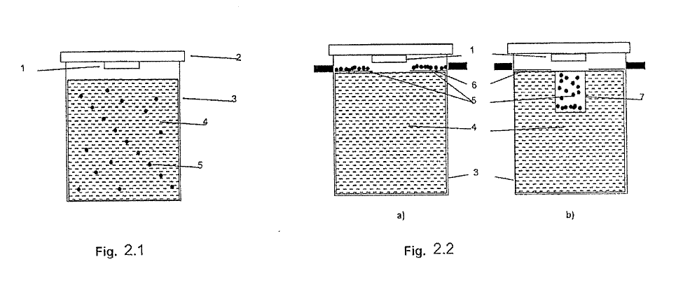

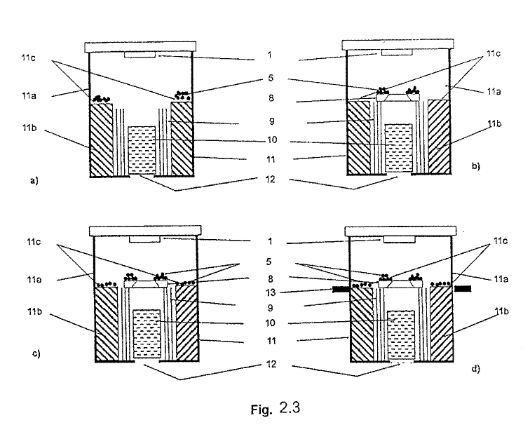

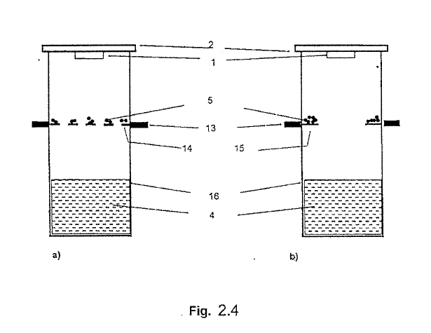

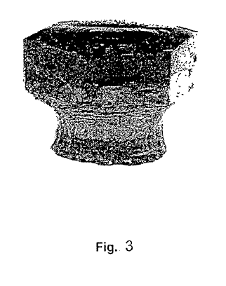

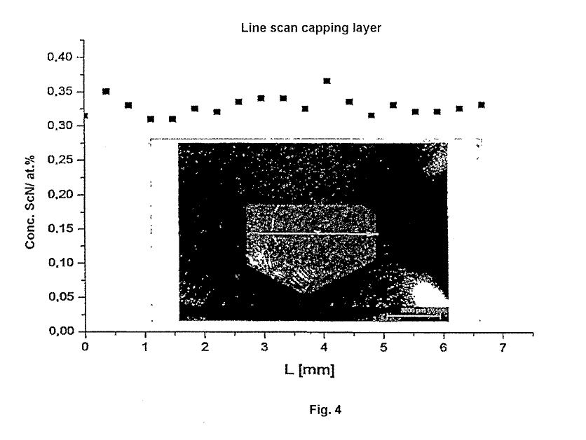

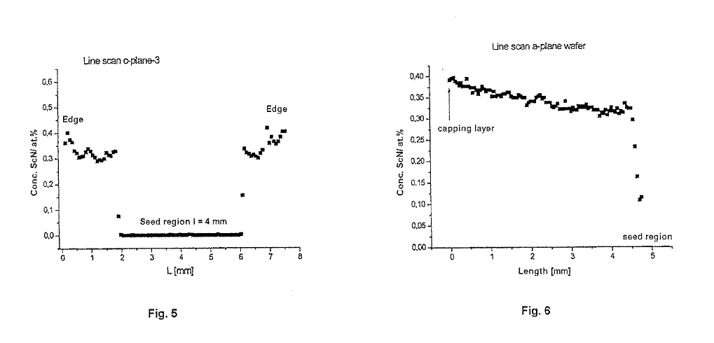

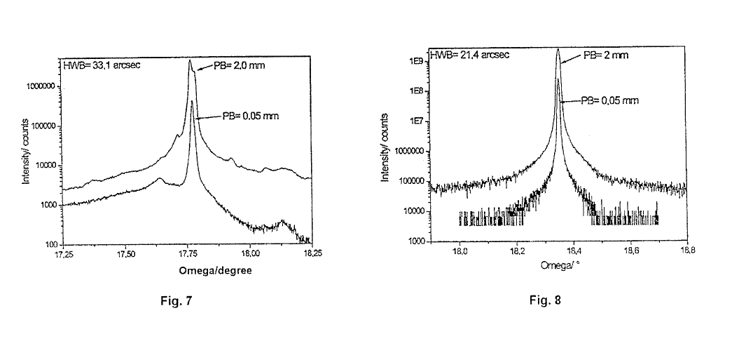

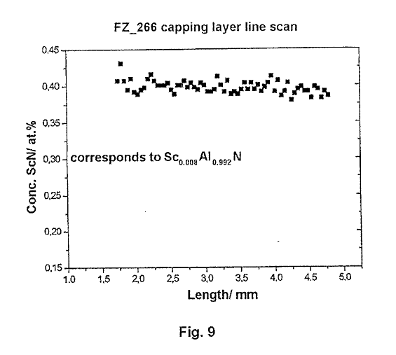

FIG. 2.4 long crucible 16;

2.4a) with diaphragm 14 to accommodate doping material (powder/granulate/etc); with and without external contact 13, source material 4 in lower region of crucible;

2.4b) with step 15 to accommodate doping material (powder/granulate/etc); with and without external contact 13, source material 4 in lower region of crucible;

FIG. 3 Sc:AlN single crystal, as-grown (sample FZ_221);

FIG. 4 XRF line scan over the “as-grown” capping layer of sample FZ_221;

FIG. 5 XRF line scan over a c-plane wafer near seed in sample FZ_221;

FIG. 6 XRF line scan over an a-plane wafer (FZ_221);

FIG. 7 rocking curve of Sc:AlN capping layer FZ_221; primary beam apertures 2 and 0.05 mm; open detector; result indicates the presence of a plurality of grains;

FIG. 8 rocking curve of capping layer of Sc:AlN (FZ_266); peak width at half height of 21.4 arcsec;

FIG. 9 XRF line scan on capping layer (FZ_266), ScN content at approximately 0.4 atom % ScN.

### LIST OF REFERENCE NUMERALS

1—seed/seed material
2—crucible cover
3—crucible (large)
4—source material/AlN source
5—doping material
6—apertured diaphragm (large)
7—small crucible/smaller (inner) crucible (to accommodate doping material)
8—apertured diaphragm (small)
9—heat shield(s)
10—crucible (small)/separate crucible (inner) in lower region to accommodate source material
11—crucible with steps/(differing) wall thicknesses
   11a—upper crucible region (with thinner wall)
   11b—thick-walled crucible region
   11c-(upper) face of thick-walled crucible region
12—opening
13—graphite contact
14—diaphragm
15—step
16—long crucible

### LITERATURE

I M Kneissl, T Kolbe, C Chua, V Kueller, N Lobo, J Stellmach, A Knauer, H Rodriguez, S Einfeidt, Z Yang, N M Johnson and M Weyers, Advances in group III-nitride-based deep UV light-emitting diode technology, Semicond, Sci. Technol, 26 (2011) 014036.
II Khan A, Balakrishnan K and Katona T 2008 Ultraviolet light-emitting diodes based on group three nitrides, Natom Photonics 2, 77 (2008).
III Zhang J, Hu X, Lunev A, Deng J, Bilenko Y, Katona T M, Shur M S, Gaska R and Khan M A, AlGaN Deep-Ultraviolet Light-Emitting Diodes, Japanese Journal of Applied Physics Vol. 44, No. 10, 2005, pp. 7250-7253.
IV Zhang J P, Wang H M, Gaevski M E, Chen C Q, Fareed Q, Yang J W, Simin G and Khan M A, Crack-free thick AlGaN grown on sapphire using AlN/AlGaN superlattices for strain management, 2002, Appl. Phys. Lett. 80 3542 (http://scitation.aip.org/content/aip/journal/apl/80/19/10.1063/1.1477620).
V Wang H M, Zhang J P, Chen C Q, Fareed Q, Yang J W and Khan M A, AlN/AlGaN superlattices as dislocation filter for low-threading-dislocation thick AlGaN layers on sapphire, 2002, Appl. Phys. Lett. 81, 604 (http://scitation.aip.org/content/aip/journal/apl/81/4/10.1063/1.1494858).
VI Hirayama H, Yatabe T, Noguchi N, Ohashi T and Kamata N, 2007, 231-261 nm AlGaN deep-ultraviolet light-emitting diodes fabricated on AlN multilayer buffers grown by ammonia pulse-flow method on sapphire, 2007, Appl. Phys. Lett. 91, 071901.
VII M. Shatalov, W, Sun, A. Lunev, X. Hu, A. Dobrinsky, Y. Bilenko, J. Yang et al, AlGaN Deep-Ultraviolet Light-Emitting Diodes with External Quantum Efficiency above 10%, 2012, Applied Physics Express, Volume 5, Number 8, 082101.
VIII H. Hirayama, N. Maeda, S. Fujikawa, S. Toyoda, N. Kamata; Recent progress and future prospects of AlGaN-based high-efficiency deep-ultraviolet light-emitting diodes; Japanese Journal of Applied Physics 53, 100209 (2014)
IX H. Yoshida, Y. Yamashita, M, Kuwabara, and H. Kan, Demonstration of an ultraviolet 336 nm AlGaN multiple-quantum-well laser diode, 2008, Appl. Phys, Lett, 93, 241106 (http://scitation.aip.org/content/aip/journal/apl/93/24/10.1063/1.3050539).
X Kueller V, Knauer A, Brunner F, Zeimer U, Rodriguez H, Weyers M and Kneissl M, 2010, Growth of AlGaN and AlN on patterned AlN/sapphire templates, 2011, Journal of Crystal Growth, Volume 315, Issue 1, 15 Jan. 2011, Pages 200-203.
XI Zhang, S. Gautier, C.-Y. Cho, E. Cicek, Z. Vashaei, R. McClintock, C. Bayram, Y. Bei, and M. Razeghi, Near milliwatt power AlGaN-based ultraviolet light emitting diodes based on lateral epitaxial overgrowth of AlN on Si(111), 2013, Applied Physics Letters, vol. 102, p. 011106,
XII Guogiang Li, Wenliang Wang, Weijia Yang, Haiyan Wang, Epitaxial growth of group III-nitride films by pulsed laser deposition and their use in the development of LED devices, 2015, Surface Science Reports, Volume 70, Issue 3, November 2015, Pages 380-423.
XIII H. Okumura, T. Kimoto, and J. Sudá, “Over-700-nm Critical Thickness of AlN Grown on 6H-SiC(0001) by Molecular Beam Epitaxy,” Applied Physics Express, vol. 5, p. 105502, 2012.
XIV L, Liu, J. H. Edgar, Substrates for gallium nitride epitaxy, 2002, Materials Science and Engineering: R: Reports; Volume 37, Issue 3, Pages 61-128 (30 Apr. 2002)
XV T. Kinoshita, K. Hironaka, T. Obata, T. Nagashima, R. Dalmau, R. Schlesser, B. Moody, J. Xie, S. Inoue, Y. Kumagai, A. Koukitu, and Z. Sitar, Deep-ultraviolet light-emitting diodes fabricated on AlN substrates prepared by hydride vapor phase epitaxy, 2012, Applied Physics Express, 5(12), 122101.
XVI T. Kinoshita, T. Obata, T. Nagashima, H, Yanagi, B. Moody, S. Mita, S, Inoue, Y. Kumagai, A. Koukitu, and Z. Sitar, Performance and Reliability of Deep-Ultraviolet Light-Emitting Diodes Fabricated on AlN Substrates Prepared by Hydride Vapor Phase Epitaxy, Applied Physics Express, 6(13), 092103,
XVII C Hartmann, A Dittmar, J Wollweber and M Bickermann, Bulk AlN growth by physical vapour transport, 2014, Semiconductor Science and Technology, Volume 29, Number 8.
XVIII Robert T. Bondokov, Kenneth E. Morgan, Glen A. Slack, and Leo J. Schowalter, Fabrication and Characterization of 2-inch diameter AlN Single-Crystal Wafers cut From bulk crystals. 2007, Materials Research Society/Mater. Res. Soc. Syrup, Proc. 2007/MRS Proceedings, 955, 0955-I03-08 doi:10.1557/PROC-0955-I03-08.
XIX R. Dalmau, B. Moody, R. Schlesser, S. Mita, J. Xie, M. Feneberg, B. Neuschl, K. Thonke, R. Collazo, A. Rice, J. Tweedie, Z. SitarDalmau, Growth and Characterization of AlN and AlGaN Epitaxial Films on AlN single crystal substrates, Journal of The Electrochemical Society. 158(5) H530-H535 (2011).
XX Wu T. Kinoshita, K. Hironaka, T. Obata, T. Nagashima, R. Dalmau, R. Schlesser, B. Moody, J. Xie, S. Inoue, Y. Kumagai, A. Koukitu, and Z. Sitar, Deep-Ultraviolet Light-Emitting Diodes Fabricated on AlN Substrates Prepared by Hydride Vapor Phase Epitaxy, 2012, Appl. Phys. Express 5, 122101.
XXI T. Erlbacher, M. Bickermann, B. Kallinger, E. Meissner, A. Bauer, L. Frey; Ohmic and rectifying contacts on bulk AlN for radiation detector applications; Phys. Status Solidi C 9, No. 3-4, 968-971 (2012)
XXII M. Jayasakthi, R. Ramesh, P. Arivazhagan, R. Loganathan, K. Prabakaran, M. Balaji, K. Baskar, Structural and optical characterization of AlGaN/GaN layers, 2014, Journal of Crystal Growth, Volume 401, 1 Sep. 2014, Pages 527-531, Proceedings of 17th International Conference on Crystal Growth and Epitaxy (ICCGE-17), (http://vvww.sciencedirect.com/science/article/pii/S002202481400222X).
XXIII T. Mukai, S. Hagahama, T. Yanamoto, M. Sano, Expanding Emission Wavelength on Nitride Light-Emitting Devices, 2002, Physica Status Solidi (a), Volume 192, Issue 2, pages 261-268 (August 2002).
XXIV P. Perlin, P. Wisniewski, T. Swietlik, L. Gorczyca, M. Leszczyn'ski, T. Suski, P. Prystawko, R. Czarnecki, K. Krowicki, I. Grzegory, S. Porowski, 2004, Abstract Book of the Third International Workshop on Bulk Nitride Semiconductors, p. 59.
XXV K. Akita, T. Nakamura, H. Hirayama, Effects of GaN substrates on InAlGaN quaternary UV LEDs, 2004, Physica Status Solidi (a), Volume 201, Issue 12, pages 2624-2627 (September 2004).
XXVI A. Gassmann, T. Suski, N. Newman, C. Kisieiowski, E. Jones, E. R. Weber, Z. Liliental-Weber, M. D. Rubin, H. I. Helava, I. Grzegory, M. Bockowski, J. Jun, S. Porowski, Homoepitaxial growth of GaN using molecular beam epitaxy, 1996, Journal of Applied Physics (Impact Factor: 2.18). September 1996; 80(4):2195-2198.
XXVII V. F. Mymrina, K. A. Bulashevicha, N. I. Padalskayaa, S. Yu. Karpov, Bandgap engineering of electronic and optoelectronic devices on native AlN and GaN substrates-A modelling insight, 2005, Journal of Crystal Growth, Volume 281, Issue 1, Pages 115-124 (15 Jul. 2005).
XXVIII R. P. Vaudo, X. Xu, C. Loria, A. D. Salant, J. S. Flynn, G. R. Brandes, GaN Boule Growth: A Pathway to GaN Wafers with Improved Material Quality, 2002, Physics Status Solidi (a), Volume 194, Issue 2, pages 494-497 (December 2002),
XXIX Bohnen et al, ScAlN nanowires: ScAlN nanowires: A cathodoluminescence study, 2009, Journal of Crystal Growth, Volume 311, Issue 11, Pages 3147-3151 (15 May 2009).
XXX Bohnen et al, Growth of scandium aluminum nitride nanowires on ScN(111) films on 6H-SiC substrates by HYPE, Physica Status Solidi (a), 206, No. 12, 2809-2815 (DOI 10.1002/pssa.200925060).
XXXI W. W. Lei, D. Liu, P. W. Zhu, X. H. Chen, Q. Zhao, G, H, Wen, Q. L, Cui, and G. T. Zou, Ferromagnetic Sc-doped AlN sixfold-symmetrical hierarchical nanostructures, 2009, Applied Physics Letters 95, 162501.
XXXII Lei W, Liu D, Ma Y, Chen X, Tian F, Zhu P, Chen X, Cui O, Zou G., Scandium-Doped AlN 1D Hexagonal Nanoprisms—A Class of Room-Temperature Ferromagnetic Materials, 2010, Angewandte Chemie International Edition, Volume 49, Issue 1, pages 173-176, Jan. 4, 2010.
XXXIII M. A. Moram, S. Zhang, ScGaN and ScAlN: Emerging nitride materials, 2014, Journal of Materials Chemistry A, Issue 17, 6042-6050 (www.rsc.org/MaterialsA).
XXXIV Siyuan Zhang, David Holec, Wai Yuen Fu, Colin J. Humphreys and Michelle A. Moram, Tunable optoelectronic and ferroelectric properties in Sc-based III-nitrides, 2013, Journal of Applied Physics 114, 133510 (http://dx.doi.org/10.1063/1.4824179).
XXXV S. Zhang, W. Y. Fu, D. Holec, C. J. Humphreys and M. A. Moram, Elastic constants and critical thicknesses of ScGaN and ScAlN, 2013, Journal of Applied Physics 114, 243516 (http://dx.doi.org/10.1063/1.4848036).
XXXVI Ridong Cong, Hongyang Zhu, Xiaoxin Wu, Chunli Ma, Guangchao Yin, Xiaojun Xie, and Qiliang Cui, Doping Effect on High-Pressure Behaviors of Sc,Y-doped AlN Nanoprisms, 2013, The Journal of Physical Chemistry C, 117 (8), pp 4304-4308.
XXXVII Zheng Gu, J. H. Edgar, J. W. Pomeroy, Martin Kuball, D. W. Coffey, Crystal growth and properties of scandium nitride, 2004, Journal of Materials Science Materials in Electronics (Impact Factor: 1.57). July 2004; 15(8):555-559. DOI: 10.1023/B:JMSE.0000032591.54107.2c.

1. A method for the production of single crystal aluminium nitride doped with scandium and/or yttrium, with scandium and/or yttrium contents in the range 0.01 atom % to 50 atom % with respect to 100 atom % of the total quantity of the doped aluminium nitride, wherein in a crucible, in the presence of a gas selected from nitrogen or a noble gas, or a mixture of nitrogen and a noble gas: a) a doping material selected from scandium, yttrium, scandium nitride or yttrium nitride or a mixture thereof; and b) a source material formed from aluminium nitride are sublimated and recondensed onto a seed material which is selected from aluminium nitride or aluminium nitride doped with scandium and/or yttrium.

2. The method for the production of single crystalline aluminium nitride doped with scandium and/or yttrium of claim 1, wherein the temperature of the doping material is 1K to 400K higher than the temperature of the source material.

3. The method for the production of single crystalline aluminium nitride doped with scandium and/or yttrium of claim 1, wherein the temperature of the doping material is the same as or lower than the temperature of the source material.

4. The method for the production of single crystalline aluminium nitride doped with scandium and/or yttrium of claim 1, wherein the temperature of the source material is 1K to 300K higher than the temperature of the seed material.

5. The method for the production of single crystalline aluminium nitride doped with scandium and/or yttrium of claim 1, wherein the total gas pressure is in the range 10 to 1200 mbar, preferably in the range 200 to 1000 mbar, particularly preferably in the range 500 to 900 mbar.

6. The method for the production of single crystalline aluminium nitride doped with scandium and/or yttrium of claim 1, wherein a heating means is disposed or can be disposed outside the crucible, preferably at least in the lower region of the crucible, wherein the temperature provided by the heating means is in the range 1500° C. to 2700° C.

7. The method for the production of single crystalline aluminium nitride doped with scandium and/or yttrium of claim 1, wherein the seed material is disposed or can be disposed in the crucible separated from or separable from the source and doping material, separated from or separable from or disposed or can be disposed above the source and doping material.

8. The method for the production of single crystalline aluminium nitride doped with scandium and/or yttrium of claim 1, wherein in the crucible, the source and doping material are completely or partially admixed, sintered or present as aluminium nitride doped with scandium and/or yttrium.

9. The method for the production of single crystalline aluminium nitride doped with scandium and/or yttrium of claim 1, wherein in the crucible, the source and doping materials are spatially separated or separable or spaced apart or can be spaced apart, wherein the mean separation of the doping material from the seed material is less than the mean separation of the source material from the seed material.

10. Single crystal aluminium nitride doped with yttrium, produced in accordance with the method of claim 1.

11. Single crystal aluminium nitride doped with scandium and yttrium, produced in accordance with the method of claim 1.

12. Single crystal aluminium nitride doped with scandium, having geometric dimensions of at least 3 mm×3 mm×100 μm, produced in accordance with the method of claim 1.

13. Single crystal aluminium nitride doped with yttrium, having geometric dimensions of at least 3 mm×3 mm×100 μm, produced in accordance with the method of claim 1.

14. Single crystal aluminium nitride doped with scandium and yttrium, having geometric dimensions of at least 3 mm×3 mm×100 μm, produced in accordance with the method of claim 1.

15. Use of single crystal aluminium nitride doped with scandium in accordance with the method of claim 1, as a substrate (wafer) for the production of layers or stacks of layers formed from aluminium gallium nitride, indium aluminium nitride or indium aluminium gallium nitride, preferably with a layer thickness of more than 2 nm, more preferably with a layer thickness of 100 nm to 50 μm.

16. Use of single crystal aluminium nitride doped with yttrium as a substrate (wafer) for the production of layers or stacks of layers formed from aluminium gallium nitride, indium aluminium nitride or indium aluminium gallium nitride, preferably with a layer thickness of more than 2 nm, more preferably with a layer thickness of 100 nm to 50 μm.

17. Use of single crystal aluminium nitride doped with scandium and yttrium as a substrate (wafer) for the production of layers or stacks of layers formed from aluminium gallium nitride, indium aluminium nitride or indium aluminium gallium nitride, preferably with a layer thickness of more than 2 nm, more preferably with a layer thickness of 100 nm to 50 μm.

18. A component comprising a first layer consisting of layers or stacks of layers of aluminium gallium nitride, indium aluminium nitride or indium aluminium gallium nitride which are on single crystalline aluminium nitride substrates doped with scandium and/or yttrium, which are produced in accordance with the method of claim 1.

19. The component of claim 18, comprising at least one further layer formed from crystalline aluminium nitride or a layer formed from aluminium gallium nitride, which contains more aluminium (as an atomic percentage) than the first layer.

20. A device, in particular for carrying out the method of claim 1, in particular for the production of single crystal aluminium nitride doped with scandium and/or yttrium, with scandium and/or yttrium contents in the range 0.01 atom % to 50 atom % with respect to 100 atom % total quantity of the doped aluminium nitride, comprising a crucible which in a first region, is provided with a first means in which a seed material can be accommodated or is, and in a second region, is provided with at least one second means in which a source material and/or a doping material can be accommodated or is/are accommodated.

21. The device of claim 20, characterized in that the at least one second means in which a source and/or a doping material can be or is/are accommodated comprises at least two said second means, of which one is configured to accommodate the source material and the other is configured to accommodate the doping material, wherein the mean separation of the second means for accommodating the doping material from the first means for accommodating the seed material is less than the mean separation of the second means for accommodating the source material from the first means for accommodating the seed material.

22. The device of claim 21, characterized in that the second means for accommodating the source material is formed by the lower inner region of the crucible and the second means for accommodating the doping material is disposed or can be disposed above the means for accommodating the source material and below the means for accommodating the seed.

23. The device of claim 21, wherein the lower region of the crucible has a thicker wall than in the upper region, which has an approximately horizontal upper face.

24. The device of claim 21, characterized in that in the inside of the crucible within the thicker wall, a separate crucible is disposed or can be disposed which forms the second means for accommodating the source material, and/or one or more heat shields, with a further separate device which is disposed or can be disposed thereon.

25. The device of claim 23, wherein the upper face of the thicker wall and/or the further separate device which is disposed on the heat shield(s) forms the second means for accommodating the doping material.
